(19) United States
(12) Patent Application Publication
(10) Pub. No.: US 2009/0173379 A1
(43) Pub. Date: Jul. 9, 2009

(54) SOLAR CELL HAVING IMPROVED ELECTRODE STRUCTURE

(75) Inventor: Dae-Won KIM, Suwon-si (KR)

Correspondence Address: STEIN MCEWEN, LLP, 1400 EYE STREET, NW, SUITE 300, WASHINGTON, DC, 20005, US

(73) Assignee: Samsung SDI Co., Ltd., Suwon-si (KR)

(21) Appl. No.: 12/098,626

(22) Filed: Apr. 7, 2008

(30) Foreign Application Priority Data
Jan. 4, 2008 (KR) 10-2008-0001267

(51) Int. Cl. H01L 31/0224; H01L 31/0264

(52) U.S. Cl. 136/256; 136/261; 257/459

(57) ABSTRACT

A solar cell having an improved electrode structure includes a semiconductor substrate of a first conductive type, a first electrode, an emitter portion of a second conductive type, and a second electrode. The semiconductor substrate has first and second surfaces opposite to each other. The first electrode is electrically connected to the first surface of the semiconductor substrate. The emitter portion is formed adjacent to the second surface of the semiconductor substrate. The second electrode is electrically connected to the emitter portion. The first electrode includes a first electrode portion partially formed on the first surface of the semiconductor substrate and a second electrode portion formed on the first surface of the semiconductor substrate to cover the first electrode portion.

### CROSS-REFERENCE TO RELATED APPLICATIONS

This application claims the benefit of Korean Patent Application No. 2008-0001267 filed in the Korean Intellectual Property Office on Jan. 4, 2008, the entire contents of which are incorporated herein by reference.

### BACKGROUND OF THE INVENTION

1. Field of the Invention

An aspect of the present invention relates to a solar cell, and more particularly, to a solar cell having an improved electrode structure.

2. Description of the Related Art

A solar cell generates electrical energy from solar energy. The solar cell is environmentally friendly, and its energy source is endless. In addition, the solar cell has a long lifespan. Examples of solar cells include a semiconductor solar cell and a dye-sensitized solar cell according to how electrical energy is generated from solar energy.

In the semiconductor solar cell, a base and an emitter portion are formed on a semiconductor substrate, which have different types of conductivity, to form a p-n junction. Front electrodes are formed on the emitter portion, and rear electrodes and a rear passivation layer are formed on a rear surface of the semiconductor substrate. The rear passivation layer is formed at a portion where the rear electrodes are not formed, in order to prevent a recombination of charges.

In order to maximize the effect of preventing the recombination of the charges, the area of the rear passivation layer should be increased. On the other hand, in order to reduce a loss of power by reducing resistance of the electrode, the volume of the rear electrodes should be increased. Considering the above, a scheme in which a width of the rear electrodes is reduced and a length between the rear electrodes is increased so as to secure the area of the rear passivation layer, and the rear electrodes are thickened so as to reduce the resistance of the electrodes, is applied to the semiconductor solar cell.

However, if the rear electrodes are thick, the manufacturing costs of the rear electrodes increases. In addition, if the rear electrodes are thick, the semiconductor substrate can be damaged by a stress induced from the manufacturing process including a heat treatment. To suppress the damage of the semiconductor substrate, the semiconductor substrate should also be thick. Since the semiconductor substrate is a main factor of the manufacturing cost of the solar cell and has a great effect on the same, the manufacturing cost increases greatly if the semiconductor substrate is thick. Further, the solar cell cannot be made thin because of the thick rear electrodes and the thick semiconductor substrate.

Moreover, light penetrating the semiconductor substrate can exit the solar cell through the rear passivation layer, and thus the energy conversion efficiency is low.

Meanwhile, since the rear electrodes can only be formed of a material, such as aluminum, which electrically connects to the semiconductor substrate, the type of material used for the rear electrodes is limited, and therefore the energy conversion efficiency cannot be improved to a high degree.

The above information disclosed in this Background section is only for enhancement of understanding of the background of the invention and therefore it may contain information that does not form the prior art that is already known in this country to a person of ordinary skill in the art.

### SUMMARY OF THE INVENTION

An aspect of the present invention has been made in an effort to provide a solar cell having advantages of reducing a manufacturing cost, reducing a thickness, and improving energy conversion efficiency.

An exemplary embodiment of the present invention provides a solar cell including a semiconductor substrate of a first conductive type, a first electrode, an emitter portion of a second conductive type, and a second electrode. The semiconductor substrate has a first surface and a second surface opposite to each other. The first electrode is electrically connected to the first surface of the semiconductor substrate. The emitter portion is formed adjacent to the second surface of the semiconductor substrate. The second electrode is electrically connected to the emitter portion. The first electrode includes a first electrode portion partially formed on the first surface of the semiconductor substrate and a second electrode portion formed on the first surface of the semiconductor substrate to cover the first electrode portion.

According to another aspect of the present invention, the first electrode portion may include a plurality of dot electrodes spaced apart from each other. A ratio of an area of the first electrode portion to an area of the semiconductor substrate may be within a range of 0.01 to 0.1. The second electrode portion may be formed on substantially the entire first surface of the semiconductor substrate.

According to another aspect of the present invention, the second electrode portion may have higher electric conductivity than that of the first electrode portion. The second electrode portion may act as a reflective layer.

According to another aspect of the present invention, the first electrode portion may include aluminum, and the second electrode portion may include at least one material selected from a group consisting of silver, gold, platinum, and copper.

According to another aspect of the present invention, the solar cell may further include a first passivation layer formed between the semiconductor substrate and the second electrode portion and at a portion where the first electrode portion is not formed. The second electrode portion may cover the first electrode portion and the first passivation layer.

According to another aspect of the present invention, the first passivation layer may include amorphous silicon. The first electrode portion may include a connecting portion including aluminum and silicon. The connecting portion may be formed on the entire first electrode portion. The first passivation layer may have a thickness of 1 to 100 nm. The first passivation layer may have a thickness of 5 to 20 nm.

According to another aspect of the present invention, the solar cell may further include an anti-reflective layer formed on the emitter portion. The anti-reflective layer may include silicon nitride or a transparent conductive material. The solar cell may further include a second passivation layer formed between the anti-reflective layer and the emitter portion, and include amorphous silicon.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a cross-sectional view of a solar cell according to an exemplary embodiment of the present invention;

FIG. 2 is a bottom plan view of the solar cell according to an exemplary embodiment of the present invention;

FIG. 3 is a graph showing an effective lifetime of electrons according to a thickness of an amorphous silicon layer;

FIG. 4 is a flowchart showing a manufacturing method of a solar cell according to an exemplary embodiment of the present invention; and

FIG. 5A to FIG. 5H are cross-sectional views, each showing an operation of the manufacturing method of the solar cell according to an exemplary embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

Hereinafter, an embodiment of a solar cell and a manufacturing method thereof will be described with reference to the accompanying drawings. The described embodiments may be modified in various different ways, all without departing from the spirit or scope of the present invention. The drawings and description are to be regarded as illustrative in nature and not restrictive.

Throughout this specification and the claims that follow, when it is described that an element is “formed on” another element, the element may be directly formed on the other element or formed on the other element with one or more elements disposed therebetween. In addition, unless explicitly described to the contrary, the word “comprise” and variations such as “comprises” or “comprising” will be understood to imply the inclusion of stated elements but not the exclusion of any other elements.

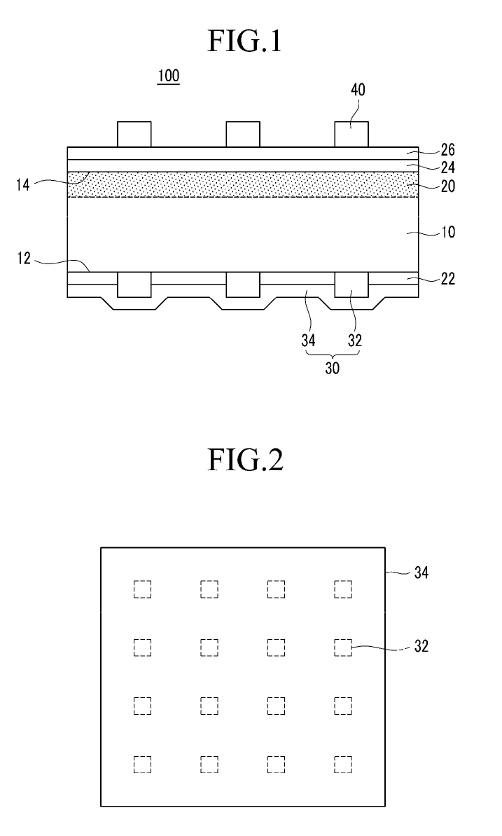

FIG. 1 is a cross-sectional view of a solar cell according to an exemplary embodiment of the present invention, and FIG. 2 is a bottom plan view of the solar cell according to an exemplary embodiment of the present invention.

Referring to FIG. 1, a solar cell 100 of the present exemplary embodiment includes a semiconductor substrate 10, at least one first electrode (hereinafter, “rear electrode”) 30, an emitter portion 20, and at least one second electrode (hereinafter, “front electrode”) 40. The semiconductor substrate 10 has a first surface (hereinafter, “rear surface”) 12 and a second surface (hereinafter, “front surface”) 14 opposite to each other. The first electrode 30 is electrically connected to the second surface 12 of the semiconductor substrate 10, the emitter portion 20 is formed adjacent to the second surface 14 of the semiconductor substrate 10, and the front electrode 40 is electrically connected to the emitter portion 20.

A first passivation layer (hereinafter, “rear passivation layer”) 22 is formed on the rear surface 12 of the semiconductor substrate 10, and a second passivation layer (hereinafter, “front passivation layer”) 24 and an anti-reflective layer 26 are formed on the emitter portion 20.

Hereinafter, the solar cell 100 will be described in more detail.

In the present exemplary embodiment, the semiconductor substrate 10 is formed of crystalline silicon and is of a first conductive type. The first conductive type is a p-type in the present exemplary embodiment. However, the present invention is not limited thereto. Thus, the semiconductor substrate 10 may be of an n-type conductive type, and may be formed of various semiconductor materials other than silicon.

The emitter portion 20 is formed adjacent to the second surface 14 of the semiconductor substrate 10 and is of a second conductive type. The second conductive type is an n-type in the present exemplary embodiment. It is sufficient that the second conductive type of the emitter portion 12 is opposite to the first conductive type of the semiconductor substrate 10 to form a p-n junction. Thus, when the semiconductor substrate 10 is of an n-type conductive type, the emitter portion 20 may be of a p-conductive type.

The emitter portion 20 may be formed by doping a dopant such as phosphor (P), arsenic (As), and antimony (Sb) on the front surface 14 of the semiconductor substrate 10. However, the present invention is not limiter thereto. Thus, the emitter portion may be formed as a layer separated from the semiconductor substrate and stacked on the semiconductor substrate.

The rear passivation layer 22, and the rear electrode 30 which include a first electrode portion 32 and a second electrode portion 34, are formed on the rear surface 12 of the semiconductor substrate 10.

That is, the first electrode portion 32 of the rear electrode 30 is partially formed on the rear surface 12 of the semiconductor substrate 10, and the second electrode portion 34 is formed on substantially the entire rear surface 12 of the semiconductor substrate 10 and covers the first electrode portion. The rear passivation layer 22 is formed at a portion where the first electrode portion 32 is not formed and between the semiconductor substrate 10 and the second electrode portion 34.

The phrase “the second electrode portion 34 is formed on substantially the entire rear surface 12” includes a situation when the second electrode portion 34 is not formed on portions of the rear surface 12 such as its edges in order to prevent an unwanted short circuit between the emitter portion 20 and the second electrode portion 34. This phrase also includes a case when the second electrode portion 34 is formed on the entire rear surface 12.

The rear passivation layer 22 prevents charges from recombining that may be induced at a portion adjacent to the rear surface 12 of the semiconductor substrate 10. A plurality of dangling bonds exist adjacent to the rear surface 12 of the semiconductor substrate 10. If the charges are combined to form defects such as the dangling bonds, the charges are lost at the rear surface 12. Therefore, the rear passivation layer 22 is formed on the rear surface 12 of the semiconductor substrate 10 to suppress the recombination of the charges.

The first electrode portion 32 connects the semiconductor substrate 10 to the second electrode portion 34, and the second electrode portion 34 collects charges generated at the semiconductor substrate 10 through the first electrode portion 32.

A connecting portion is formed at least at a portion of the first electrode portion 32 adjacent to the semiconductor substrate 10, and connects the semiconductor substrate 10 to the first electrode portion 32. The connecting portion is formed by diffusion of a material included in the rear passivation layer 22 and a conductive material included in the first electrode portion 32. In the present exemplary embodiment, the entire first electrode portion 32 is formed of the connecting portion. However, the present invention is not limited thereto. Thus, the connection portion may only be formed on a portion of the first electrode portion 32 adjacent to the semiconductor substrate 10.

The conductive material of the first electrode portion 32 may be a material that can be easily diffused with the material of the rear passivation layer 22. For example, the rear passivation layer 22 may be formed of amorphous silicon, and the first electrode portions 32 may include aluminum. That is, the connecting portion of the first electrode portion 32 may be formed of a compound of aluminum and silicon.

In the present exemplary embodiment, since it is sufficient that the first electrode portion 32 be connected to the semiconductor substrate 10, the first electrode portion 32 may be formed within a small area. Thus, the rear passivation layer 22, which is formed at the portion where the first electrode portions 32 are not formed, can be formed in a large area. Accordingly, the effect of preventing charges from recombining can be improved by the rear passivation layer 22.

As shown in FIG. 2, the first electrode portion 32 may include a plurality of dot electrodes so as to maximize the area of the rear passivation layer 22. In the present exemplary embodiment, the plurality of dot electrodes are distributed over the rear surface 12 of the semiconductor substrate 10, and thus the second electrode portion 34 can be uniformly connected to the semiconductor substrate 10 over the whole semiconductor substrate 10.

A ratio of an area of the first electrode portions 32 to an area of the semiconductor substrate 10 is within a range of 0.01 to 0.1. If the ratio is over 0.1, the area of the rear passivation layer 22 decreases and the effect of preventing the charges from recombining may be reduced. If the ratio is less than 0.01, the first electrode portion 32 may be unstably connected to the semiconductor substrate 10. However, the present invention is not limited thereto and has various ratios. Thus, in order to prevent the charges from recombining, the ratio may be less 0.01.

The second electrode portion 34 may have greater electric conductivity than that of the first electrode portion 32. That is, the second electrode portion 34 may be formed of a material having a specific resistance lower than that of the first electrode portion 32. Because the second electrode portion 34 has the high electric conductivity, the second electrode portions 34 can collect the charges excellently and the power consumption can be reduced.

In the present exemplary embodiment, the second electrode portion 34 may be formed of a material having excellent reflectivity so that the second electrode portion 34 can act as a reflective layer. The second electrode portion 34 reflects the light penetrating the rear passivation layer 22 to the inside of the solar cell 100, thereby improving a ratio of utilization of the light.

Considering the electric conductivity and the reflectivity, the second electrode portion 34 may be formed of silver (Ag), gold (Au), platinum (Pt), or copper (Cu). Particularly, when the second electrode portion 34 is formed of silver, the energy conversion efficiency of the solar cell 100 can be more improved by the high electric conductivity and the high reflectivity of silver. In addition, the second electrode portion 34 can be excellently connected to an external terminal due to the good soldering properties of silver.

The rear electrode 30 of the present exemplary embodiment includes the first electrode portion 32 connected to the semiconductor substrate 10 and the second electrode portion 34 collecting the charges. Accordingly, the first electrode portion 32 may be formed within a small area, thereby improving the effect of the rear passivation layer 22. The second electrode portion 34 having the high electric conductivity and the high reflectivity may be formed on the whole area. As a result, the energy conversion efficiency of the solar cell 100 can be improved.

In addition, the rear electrode 30 can be thin because of the excellent electric conductivity of the second electrode portion 34 in the present exemplary embodiment. Therefore, since the stress induced by a process of manufacturing the solar cell, including a heat treatment can be reduced, thus reducing the damage of the semiconductor substrate 10. Additionally, the semiconductor substrate 10 can be thin. Thus, the solar cell 100 can be thinner. Further, the manufacturing cost of the solar cell 100 can be decreased because the rear electrode 30 and the semiconductor substrate 10 are thin.

The front passivation layer 24, the anti-reflective layer 26, and the front electrode 40 are sequentially formed on the emitter portion 20.

The front passivation layer 24 prevents the charges from recombining with defects on the front surface 14 of the semiconductor substrate 10. For example, the front passivation layer 24 is formed of amorphous silicon. Since the front passivation layer 24 is formed of the same material as the rear passivation layer 22, the front passivation layer 24 and the rear passivation layer 22 can be simultaneously formed in the same process. Thus, the manufacturing process can be simplified.

The anti-reflective layer 26 prevents a loss of light induced by reflection. The anti-reflective layer 26 may be formed of silicon nitride (SiNₓ) or a transparent conductive material.

When the anti-reflective layer 26 is formed of silicon nitride, the front passivation layer 24 is not necessary because the anti-reflective layer 26 can prevent a recombination of the charges. Also, when the anti-reflective layer 26 is formed of silicon nitride, the front electrode 40 is formed by a firing through process. That is, an electrode paste printed on the anti-reflective layer 26 etches the anti-reflective layer 26 by the firing through process, and is electrically connected to the emitter portion 20 in order to form the front electrode 40.

When the anti-reflective layer 26 is formed of a transparent conductive material, the anti-reflective layer 26 can also collect charges. The front electrode 40 can be formed on the anti-reflective layer 26 since the front electrode 40 is electrically connected to the emitter portion 20 by the electric conductivity of the anti-reflective layer 26. Thus, the firing through process is not necessary, and thus the manufacturing process can be simplified and the front electrode 40 can be stably formed.

The anti-reflective layer 26 includes zinc oxide (ZnO) as a main substance, and may additionally include indium (In), gallium (Ga), aluminum (Al), fluorine (F), or hydrogen (H).

For example, the front electrode 40 has a comb shape having a plurality of stripe electrodes and a connection electrode connecting the plurality of stripe electrodes at one side. The front electrode 40 may be formed of silver (Ag).

Hereinafter, a thickness of the rear passivation layer 22 or a thickness of the front passivation layer 24, which is suitable for preventing a recombination of the charges, will be described when at least one of the rear passivation layer 22 and the front passivation layer 24 is formed of amorphous silicon. The effect of preventing the recombination of the charges, that is, the passivation effect, is estimated by measuring an effective lifetime of electrons using quasi steady state photo conductance (QSSPC).

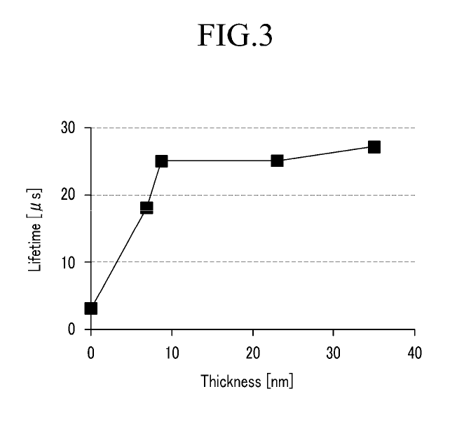

FIG. 3 is a graph showing an effective lifetime of electrons according to a thickness of an amorphous silicon layer.

To achieve a proper passivation effect, the rear passivation layer 22 or the front passivation layer 24 being an amorphous silicon layer may have a thickness larger than 1 nm. Referring to FIG. 3, when the thickness of the amorphous silicon layer is greater than about 10 nm, the effective lifetime is excellent. Thus, the rear or front passivation layer 22 or 24 may have a thickness that is greater than about 10 nm to increase the passivation effect. When the thickness of the amorphous silicon layer is greater than 100 nm, the manufacturing cost may be increased by the thick layer and the light may be absorbed to the rear and front of passivation layers 22 and 24. Thus, the rear passivation layer 22 or the front passivation layer 24 may have a thickness of less than 100 nm.

Considering the effective lifetime and thickness, the rear passivation layer 22 or the front passivation 24 may have a thickness ranging from 20 to 50 nm. However, the present invention is not limited thereto.

When light is incident on the solar cell, a positive hole and an electron pair, formed by a photoelectric effect, is separated, and thus electrons are accumulated on the n-type emitter portion 12, whereas positive holes are accumulated on the p-type semiconductor substrate 10. The charges are collected by the front and rear electrodes 30 and 40 and flow, and thus the solar cell works.

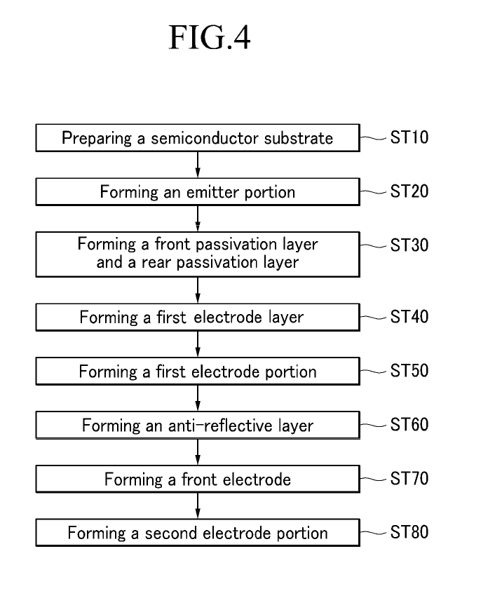

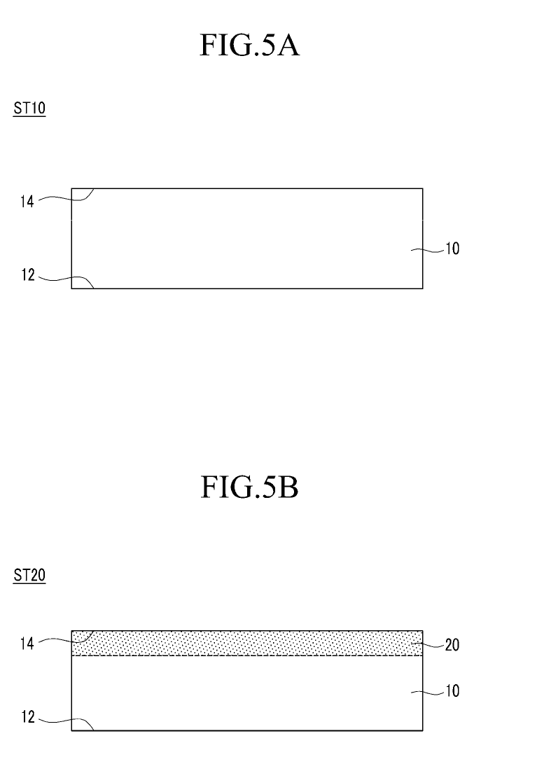

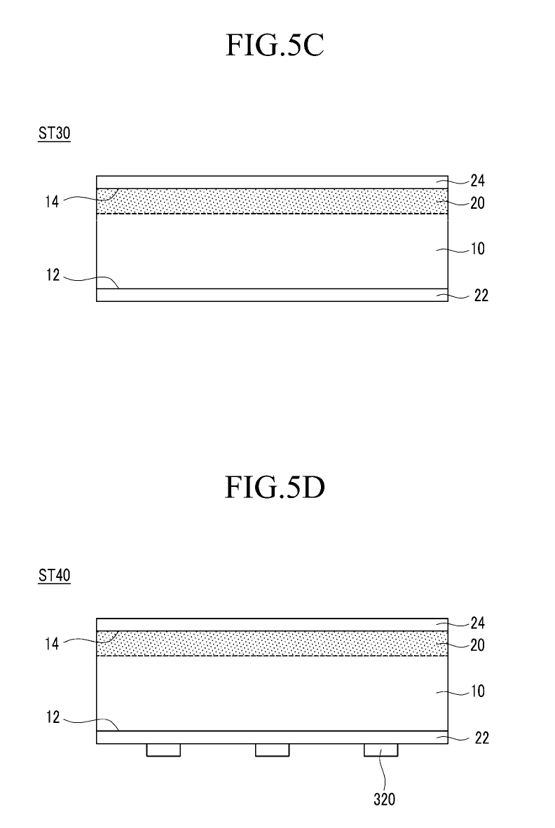

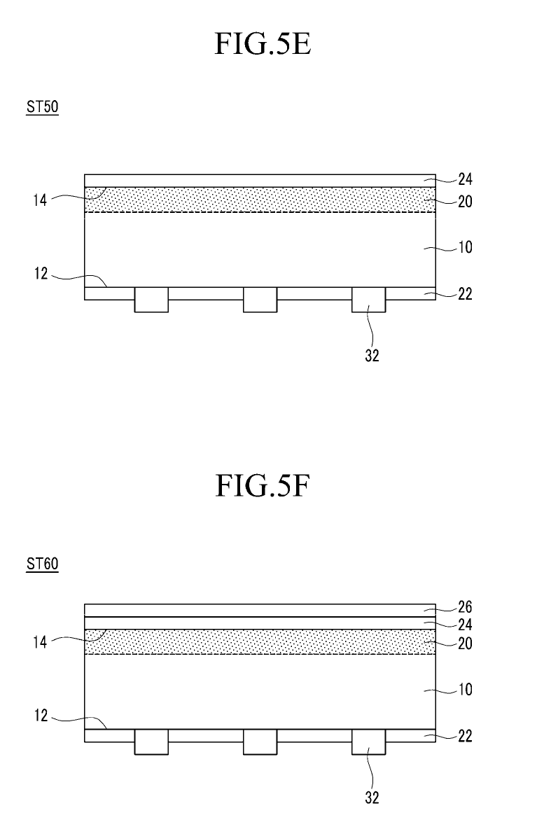

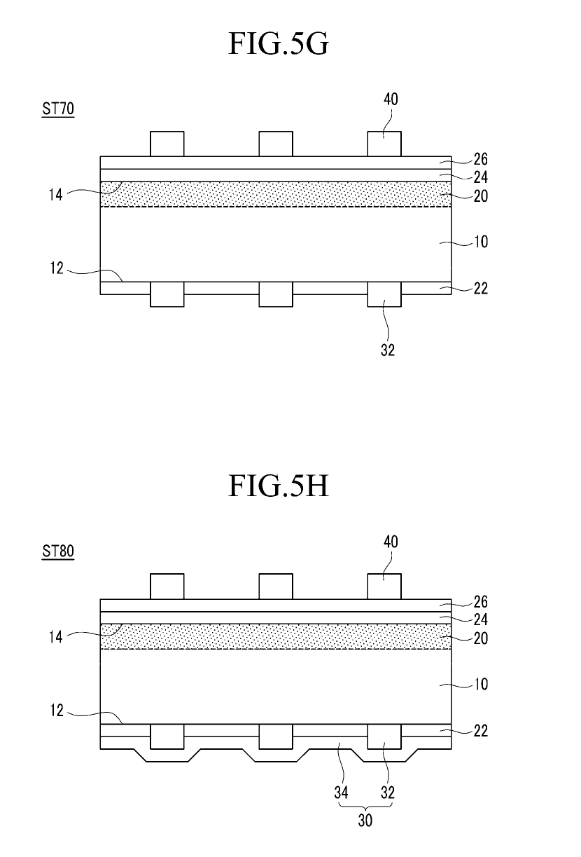

Hereinafter, an exemplary embodiment of a manufacturing method of the solar cell having the above-mentioned structure will be described with reference with FIGS. 4 and 5A to 5H. The exemplary embodiment of the manufacturing method is only for describing the solar cell, and thus the present invention is not limited thereto.

FIG. 4 is a flowchart showing a manufacturing method of a solar cell according to an exemplary embodiment of the present invention. FIG. 5A to FIG. 5H are cross-sectional views, each showing an operation of the manufacturing method of the solar cell according to an exemplary embodiment of the present invention.

Referring to FIG. 4, the manufacturing method of the solar cell according to the present exemplary embodiment includes operation ST10 of preparing a semiconductor substrate, operation ST20 of forming an emitter portion, operation ST30 of forming a front passivation layer and a rear passivation layer, operation ST40 of forming a first electrode layer, operation ST50 of forming a first electrode portion, operation ST60 of forming of an anti-reflective layer, operation ST70 of forming a front electrode, and operation ST80 of forming a second electrode portion.

Each of the operations will be described referring to FIGS. 5A to 5H, along with FIG. 4.

First, as shown in FIG. 5A, in operation ST10 of preparing a semiconductor substrate, a p-type semiconductor substrate 10 formed of silicon is prepared.

Subsequently, as shown in FIG. 5B, in operation ST20, a dopant such as phosphor, arsenic, or antimony is doped on the front surface 14 of the semiconductor substrate 10 in order to form an n-type emitter portion 20. The doping method may include a high-temperature diffusion method, a spray method, a screen printing method, and an ion shower method.

For example, phosphoryl chloride (POCl₃) is thermally pyrolyzed in a diffusion furnace, a phosphosilicate glass (PSG) layer (not shown) is formed on the surface of the semiconductor substrate 10, and phosphor in the PSG layer is diffused into the semiconductor substrate 10 in order to form the emitter portion 20. Then, the PSG is eliminated by diluted hydrofluoric acid (HF), and a portion where the phosphor is unnecessarily diffused is removed by an alkaline solution such as potassium hydroxide (KOH).

However, the present invention is not limited thereto. Thus, various dopants and doping methods may be used to form the emitter portion 20. Selectively, the emitter portion may be formed as a layer that is separated from the semiconductor substrate and stacked on the front surface of the semiconductor substrate.

Subsequently, as shown in FIG. 5C, in operation ST30, rear and front passivation layers 22 and 24 of amorphous silicon are formed on the rear and front surfaces 12 and 14 of the semiconductor substrate 10, respectively. The rear and front passivation layers 22 and 24 may be formed by plasma enhanced chemical vapor deposition (PECVD).

Subsequently, as shown in FIG. 5D, in operation ST40, first electrode layers 320 having dot shapes are formed on the rear passivation layer 22 on the semiconductor substrate 10. The first electrode layers 320 are formed by performing a vacuum plating method or sputtering method when a mask (not shown) is in close contact with the semiconductor substrate 10.

Subsequently, as shown in FIG. 5E, in operation ST50, a first electrode portion 32 including a connecting portion is formed by a heat treatment. The connecting portion is formed by reciprocal diffusion of silicon included in the rear passivation layer 22 and aluminum included in the first electrode layer 320. The connecting portion is electrically connected to the semiconductor substrate 10 with a sufficiently low contact resistance.

The heat treatment of operation ST50 can be performed in an atmosphere of an inert gas, such as nitrogen and argon, with about 3% hydrogen to prevent oxidation of silicon and aluminum, and at a temperature below the eutectic point of silicon and aluminum. According to the present exemplary embodiment, the connecting portion is formed at a temperature below the eutectic point. Therefore, the damage to the solar cell generated by the heat treatment at the high temperature can be prevented.

Subsequently, as shown in FIG. 5F, in operation ST60, an anti-reflective layer 26 consisting of a transparent conductive material is formed on the front passivation layer 24. The anti-reflective layer 26 may be formed by a sputtering method. However, the present invention is not limited thereto. Thus, the anti-reflective layer consisting of silicon nitride may be formed when the front passivation layer 24 is not formed.

Subsequently, as shown in FIG. 5G, in operation ST70, a front electrode 40 is formed on the anti-reflective layer 26. The front electrode 40 is formed by printing silver oxide nanopaste using screen printing and firing the paste. The silver oxide nanopaste includes silver oxide particles having a diameter of several tens to several hundreds of nanometers. Thereby, the formed front electrode 40 has specific resistance similar to the specific resistance of silver, that is, 1.6×10⁻⁶ Ω.cm, by firing at a low temperature of 200° C.

Subsequently, as shown in FIG. 5H, in operation ST80, a second electrode portion 34 is formed to cover the whole first electrode portion 32 and the whole rear passivation layer 22 such that the manufacturing of the rear electrode 30 is completed. The second electrode portion 34 may be formed by depositing silver, platinum, gold, or copper using a vacuum plating method or a sputtering method.

According to the present exemplary embodiment, the heat treatment in operation ST50 of forming the first electrode portions and in operation ST70 of forming the front electrode can be performed at a low temperature. Thus damage caused when manufacturing the solar cell at a high temperature can be prevented, allowing the use of various materials in the manufacturing of the solar cell. For example, a transparent conductive material that could be damaged at a high temperature can be used in the present exemplary embodiment. For example, because the heat treatment is performed at a low temperature, the anti-reflective layer 26 can be formed of the transparent conductive material.

Hereinafter, the present invention will be described in more detail referring to an experimental example and a comparative example. The experimental example is provided only for describing the present invention more fully, and the present invention is not limited thereto.

### EXPERIMENTAL EXAMPLE

A p-type silicon semiconductor substrate having a thickness of 150 μm was prepared. Phosphoryl chloride (POCl₃) was thermally pyrolyzed in a diffusion furnace, a phosphosilicate glass (PSG) layer having a thickness of 0.5 μm was thereby formed on the surface of the semiconductor substrate, and phosphor in the PSG layer was diffused into the semiconductor substrate such that an emitter portion was formed. The PSG was eliminated by diluted hydrofluoric acid (HF), and a portion where the phosphor was diffused was removed by a potassium hydroxide (KOH) solution, except for the front surface of the semiconductor substrate.

A rear passivation layer and a front passivation layer of amorphous silicon were formed on the front and rear surfaces of the semiconductor substrate, respectively. The rear and front passivation layers were formed by plasma enhanced chemical vapor deposition (PECVD)

A paste including aluminum was formed on the rear passivation layer, and heat treatment was performed in a gas atmosphere of nitrogen, with about 3% hydrogen, and at a temperature of below 500° C. such that a first electrode portion was formed.

An anti-reflective layer consisting of indium zinc oxide (IZO) was formed on the front passivation layer by a sputtering method. A front electrode was formed by printing silver oxide nanopaste using screen printing and sintering the paste.

A second electrode portion was formed to cover the first electrode portion and the rear passivation layer by a sputtering method. Accordingly, the manufacturing of the solar cell was completed.

### COMPARATIVE EXAMPLE

An n-type silicon semiconductor substrate having a thickness of 240 μm was prepared. The emitter portion was formed by the same method as the experimental example. An anti-reflective layer of silicon nitride was formed on a front surface of the semiconductor substrate by the plasma enhanced chemical vapor deposition.

A paste including aluminum was applied on the rear surface of the semiconductor substrate, and a paste including silver was applied on the front surface of the semiconductor substrate. Subsequently, a rear electrode connected to the semiconductor substrate and a front electrode connected to the emitter portion were formed by performing heat treatment at a temperature at which firing through could be generated.

The energy conversion efficiency of the solar cells according to the experimental example and the comparative example was measured according to the international standard IEC 60904. The solar cell of the experimental example has energy conversion efficiency of about 18%, while the solar cell of the comparative example had energy conversion efficiency of about 15%. That is, in the solar cell of the experimental example, the energy conversion efficiency was increased about 3%, even though the semiconductor substrate was thinner. In the solar cell according to the experimental example, the thickness of the semiconductor substrate can be reduced compared to that of the solar cell according to the comparative example by about 90 μm. Therefore, the manufacturing cost can be reduced by about 20%.

In the solar cell according to the exemplary embodiment, the first electrode (rear electrode) includes the first electrode portion to be connected to semiconductor substrate and the second electrode portion substantially collecting the charges. Thus, the energy conversion efficiency of the solar cell can be improved, the solar cell can be thinner, and the manufacturing cost of the solar cell can be reduced.

Since the first electrode portions 32 formed for an electric connection can be formed within a smaller area, the rear passivation layer can be formed over a larger area. Thus, a recombination of charges is effectively prevented. The second electrode portion consisting of a material having excellent electric conductivity can be wholly formed on the semiconductor substrate. Therefore, the charges can be effectively collected. In addition, the second electrode portion is used as a reflective layer, thereby increasing a ratio of light utilization. Accordingly, the energy conversion efficiency of the solar cell can be improved even more.

In the exemplary embodiment, the second electrode portion having excellent electric conductivity is wholly formed on the first surface (rear surface) of the semiconductor substrate. Thus, the rear electrode can be thin, and the semiconductor substrate can also be thin. As a result, the solar cell can be thin. Further, the manufacturing cost of the solar cell can be reduced.

In the present exemplary embodiment, the plurality of dot electrodes are distributed over the first surface of the semiconductor substrate as the first electrode portions, and thus the second electrode portions can be uniformly connected to the semiconductor substrate. Also, an area of the first passivation layer can be maximized.

When the first passivation layer is formed of amorphous silicon and the first electrode portion is formed of aluminum, silicon and aluminum can be diffused at a low temperature, thereby forming a connecting portion that is electrically connected to the semiconductor substrate at a low temperature. Accordingly, damage to the solar cell induced at a high temperature can be prevented.

When the second passivation layer (front passivation layer) is formed of the same material as the first passivation layer, the second passivation layer and the first passivation layer can be simultaneously formed in the same process. Thus, the manufacturing process can be simplified.

In addition, when the anti-reflective layer is formed on the transparent conductive layer, the manufacturing process can be simplified and the front electrode can be stably formed.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A solar cell, comprising:
a semiconductor substrate of a first conductive type, the semiconductor substrate having first and second surfaces opposite to each other;
a first electrode electrically connected to the first surface of the semiconductor substrate;
an emitter portion of a second conductive type, the emitter portion formed adjacent to the second surface of the semiconductor substrate; and
a second electrode electrically connected to the emitter portion,
wherein the first electrode comprises a first electrode portion partially formed on the first surface of the semiconductor substrate and a second electrode portion formed on the first surface of the semiconductor substrate to cover the first electrode portion.

2. The solar cell of claim 1, wherein the first electrode portion comprises a plurality of dot electrodes spaced apart from each other.

3. The solar cell of claim 1, wherein a ratio of an area of the first electrode portion to an area of the semiconductor substrate is within a range of 0.01 to 0.1.

4. The solar cell of claim 1, wherein the second electrode portion is formed on substantially the entire first surface of the semiconductor substrate.

5. The solar cell of claim 1, wherein the second electrode portion has greater electric conductivity than that of the first electrode portion.

6. The solar cell of claim 1, wherein the second electrode portion acts as a reflective layer.

7. The solar cell of claim 1, wherein the first electrode portion comprises aluminum, and
the second electrode portion comprises at least one material selected from a group consisting of silver, gold, platinum, and copper.

8. The solar cell of claim 1, further comprising:
a first passivation layer formed between the semiconductor substrate and the second electrode portion and at a portion where the first electrode portion is not formed,
wherein the second electrode portion covers the first electrode portion and the first passivation layer.

9. The solar cell of claim 8, wherein the first passivation layer comprises amorphous silicon.

10. The solar cell of claim 9, wherein the first electrode portion comprises a connecting portion including aluminum and silicon.

11. The solar cell of claim 10, wherein the connecting portion is formed on the entire first electrode portion.

12. The solar cell of claim 8, wherein the first passivation layer has a thickness of 1 to 100 nm.

13. The solar cell of claim 1, further comprising:
an anti-reflective layer formed on the emitter portion.

14. The solar cell of claim 13, wherein the anti-reflective layer comprises silicon nitride or a transparent conductive material.

15. The solar cell of claim 13, further comprising:
a second passivation layer formed between the anti-reflective layer and the emitter portion and comprising amorphous silicon.
